(19) United States
(12) Patent Application Publication
(10) Pub. No.: US 2026/0299563 A1
(43) Pub. Date: Oct. 1, 2026

(54) DATA-DRIVEN METHODS AND TOOLS FOR GENERATING FORMULA IN PRODUCT FORMULATION

(71) Applicant: Mars, Incorporated, McLean, VA (US)

(72) Inventors: Michael YEA, McLean, VA (US); Kangwook LEE, McLean, VA (US); John STINSON, McLean, VA (US)

(21) Appl. No.: 19/479,797

(22) PCT Filed: May 10, 2024
(86) PCT No.: PCT/US2024/028868

§ 371 Date: Oct. 29, 2025

Related U.S. Application Data
(60) Provisional application No. 63/465,962, filed on May 12, 2023.

(51) Int. Cl. G05B 19/418; G06F 30/27

(52) U.S. Cl. CPC G05B 19/4184; G05B 19/4183; G06F 30/27

(57) ABSTRACT

Systems and methods are disclosed for generating formulas for product formulation. The method includes receiving a request for a formula to design a product from at least one device associated with a user. Relevant data associated with the product is received from a plurality of data sources. A formula for designing the product is generated by applying one or more features of a trained machine-learning model. The trained machine-learning model has been trained by inputting the relevant data associated with the product into the machine-learning model; employing a supervised learning technique to optimize the machine-learning model through iterative learning algorithms; and evaluating the performance of the machine-learning model using validation techniques. The formula is presented in a user interface of at least one device associated with the user.

### CROSS-REFERENCE TO RELATED APPLICATION(S)

This application claims the benefit of priority to U.S. Provisional Application No. 63/465,962, filed on May 12, 2023, the entirety of which is incorporated herein by reference.

### TECHNICAL FIELD

The present disclosure relates generally to the field of data processing and analysis. In particular, the present disclosure relates to generating recipes via machine-learning and generative modeling techniques.

### BACKGROUND

Conventionally, recipes are developed through a series of experimental prototypes by experts. The conventional recipe designing processes are time-consuming as they require actions from different stakeholders during multiple rounds of experiments that can result in low process efficiency and a potential for mistakes. Coherence and quality remain an issue, particularly in complex and unconventional recipes, necessitating a deeper understanding of culinary principles and ingredient compatibilities. However, conventional methods struggle to adapt to the dynamic nature of culinary creativity, where recipes evolve over time. The traditional methods lack the scalability and efficiency to handle the growing recipe datasets, for example, parsing and structuring large and complex recipe datasets pose significant technical challenges to the traditional methods. Furthermore, conventional methods often struggle to capture the complexity and nuances of recipe creation, leading to limited creativity and variation in the generated recipes.

### SUMMARY OF THE DISCLOSURE

The present disclosure solves this problem and/or other problems described above or elsewhere in the present disclosure by facilitating efficient and scalable representation, retrieval, and generation of recipes.

In some embodiments, a computer-implemented method for generating formulas (e.g., recipes) in product design is disclosed. The computer-implemented method includes: receiving, by one or more processors, a request for a formula to design a product from at least one device associated with a user; receiving, by the one or more processors, relevant data associated with the product from a plurality of data sources; and generating, by the one or more processors, the formula for designing the product by applying one or more features of a trained machine-learning model, wherein the trained machine-learning model has been trained by: inputting the relevant data associated with the product into the machine-learning model; employing a supervised learning technique to optimize the machine-learning model through iterative learning algorithms; and evaluating performance of the machine-learning model using validation techniques; and generating, by the one or more processors, a presentation of the formula in a user interface of the at least one device associated with the user.

In some embodiments, a system for generating formulas in product design is disclosed. The system includes one or more processors; and at least one non-transitory computer readable medium storing instructions which, when executed by the one or more processors, cause the one or more processors to perform operations including: receiving a request for a formula to design a product from at least one device associated with a user; receiving relevant data associated with the product from a plurality of data sources; and generating the formula for designing the product by applying one or more features of a trained machine-learning model, wherein the trained machine-learning model has been trained by: inputting the relevant data associated with the product into the machine-learning model; employing a supervised learning technique to optimize the machine-learning model through iterative learning algorithms; and evaluating performance of the machine-learning model using validation techniques; and generating a presentation of the formula in a user interface of the at least one device associated with the user.

In some embodiments, a non-transitory computer readable medium for generating formulas in product design is disclosed. The non-transitory computer readable medium stores instructions which, when executed by one or more processors, cause the one or more processors to perform operations including: receiving a request for a formula to design a product from at least one device associated with a user; receiving relevant data associated with the product from a plurality of data sources; and generating the formula for designing the product by applying one or more features of a trained machine-learning model, wherein the trained machine-learning model has been trained by: inputting the relevant data associated with the product into the machine-learning model; employing a supervised learning technique to optimize the machine-learning model through iterative learning algorithms; and evaluating performance of the machine-learning model using validation techniques; and generating a presentation of the formula in a user interface of the at least one device associated with the user.

It is to be understood that both the foregoing general description and the following detailed description are example and explanatory only and are not restrictive of the detailed embodiments, as claimed.

### BRIEF DESCRIPTION OF THE DRAWINGS

The accompanying drawings, which are incorporated in and constitute a part of this specification, illustrate various example embodiments and together with the description, serve to explain the principles of the disclosed embodiments.

FIG. 1 is a diagram showing an example of a system for recipe synthesis in product development, according to aspects of the disclosure.

FIG. 2 is a flowchart of a process for recipe engineering in product design, according to aspects of the disclosure.

FIG. 3A is a product lifecycle diagram, according to aspects of the disclosure.

FIG. 3B illustrates an integrated data-driven approach to product development, according to aspects of the disclosure.

FIG. 3C illustrates a computer-guided recipe generation process, according to aspects of the disclosure.

FIG. 4 illustrates production volume by recipe and factory, according to aspects of the disclosure.

FIG. 5 is a diagram that illustrates a recipe network, according to aspects of the disclosure.

FIG. 6 illustrates a graph for recipe simplification, according to aspects of the disclosure.

FIG. 7 is a user interface diagram that illustrates a real-time recipe alert, according to aspects of the disclosure.

FIGS. 8 A-B are graph diagrams that illustrate recipe optimization, according to aspects of the disclosure.

FIG. 9 illustrates an expert system for providing advice to non-expert users, according to aspects of the disclosure.

FIG. 10 illustrates a building block for computer-guided recipe generation, according to aspects of the disclosure.

FIG. 11 illustrates a schematic structure for a computer-guided recipe generation process, according to aspects of the disclosure.

FIG. 12 shows an example machine-learning training flow chart.

FIG. 13 illustrates an implementation of a computer system that executes techniques presented herein.

### DETAILED DESCRIPTION OF EMBODIMENTS

While principles of the present disclosure are described herein with reference to illustrative embodiments for particular applications, it should be understood that the disclosure is not limited thereto. Those having ordinary skill in the art and access to the teachings provided herein will recognize additional modifications, applications, embodiments, and substitution of equivalents all fall within the scope of the embodiments described herein. Accordingly, the invention is not to be considered as limited by the foregoing description.

Various non-limiting embodiments of the present disclosure will now be described to provide an overall understanding of the principles of the structure, function, and use of systems and methods disclosed herein for generating recipes based on expert knowledge and predicted attributes from experimental data.

Conventional methods rely on predefined sets of instructions and constraints to generate recipes, which may limit their ability to capture a diverse array of ingredient combinations and flavor profiles to produce varied and innovative recipes. As a result, the generated recipes may follow predictable patterns. The traditional methods may evaluate the quality and coherence of generated recipes by relying on subjective judgments and ad-hoc criteria. Without standardized evaluation metrics, comparing different recipe becomes challenging, hindering the objective measurement of their performance. As a result, the assessment of generated recipes may vary greatly depending on individual preferences and biases, making it difficult to determine the effectiveness and reliability of different approaches.

As discussed, manually creating recipes is a time-consuming process prone to imprecision due to variations introduced by the manual process. In one example, experts may use unauthorized techniques while designing the recipes, and it is technically challenging to monitor every expert to verify that they are following appropriate regulatory procedures. In one example, experts may inadvertently use ingredients which are not acceptable to a particular consumer's dietary restrictions (e.g. diabetic, cultural or religious observances, vegetarian, etc.), resulting in undesirable outcomes due to human error.

The traditional method of manually extracting relevant features from recipe data is a labor-intensive process fraught with limitations. Human-crafted features often rely on pre-defined rules or heuristics, which may overlook subtle patterns or correlations present in the data. Moreover, the diversity and complexity of recipes make it challenging to identify all relevant features comprehensively. This approach not only requires significant human effort but also runs the risk of oversimplifying the nuanced information encoded in recipes. In one example, altering the taste profile of the confectionary or creating a new recipe with different ingredients poses a significant challenge due to the lack of streamlined methods for recipe modification. The absence of standardized framework for ingredient substitution or flavor adjustment makes it difficult for users to experiment confidently with recipe variations. The traditional methods inhibits culinary exploration and innovation highlighting the need for intuitive method that creates recipes tailored to an individual's taste, diet, or nutritional goals.

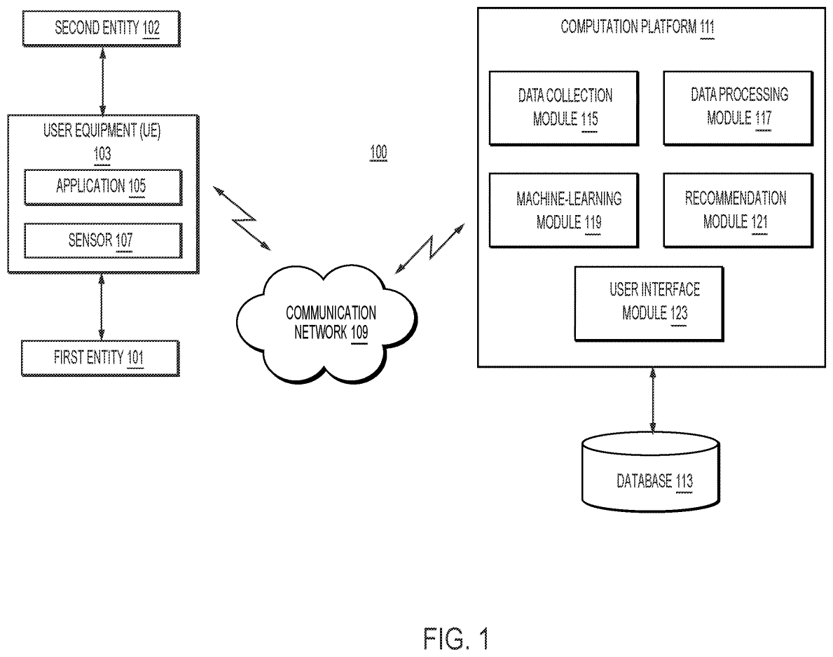

Accordingly, system 100 of FIG. 1 provides a method for automating the recipe generating process, preferably in a manner to provide greater availability, precision, and accuracy to the process. By leveraging automated algorithms, the system 100 streamlines the recipe generation process, reducing manual effort and human error. Additionally, automated methods have the potential to analyze large volumes of recipe data comprehensively, uncovering intricate patterns and correlations that might elude manual analysis. This depth of understanding enables the generation of recipes with higher precision and accuracy, as the automated system can consider a broader range of factors. Unlike conventional methods that offer generic recipes, the system 100 may incorporate user preferences, dietary restrictions, and flavor profiles to generate personalized recipes tailored to individual tastes. By integrating real-time user feedback and data analytics, the system 100 may adapt and refine recipe recommendations and continuously improve the quality of generated recipes. The system 100 may iteratively refine its algorithms and recommendation models, enhancing the accuracy and relevance of recipe suggestions.

FIG. 1, an example architecture of one or more example embodiments of the present invention, includes a system 100 that comprises first entity 101, second entity 102, user equipment (UE) 103 that includes application 105 and sensor 107, a communication network 109, a computation platform 111, and a database 113. System 100 introduces a capability to implement modern communication and data processing capabilities into methods and systems for generating recipes based on expert knowledge and predicted attributes from experimental data.

In one embodiment, the first entity 101 is an expert (e.g., a subject matter expert, food expert, legal expert, research and development expert, etc.) or a group of experts interacting with a user interface or a web interface of the UE 103 to provide experimental data. In one example embodiment, experimental data may include data on ingredient functionality (e.g., each ingredient in a product recipe adds different functionality in the final product), ingredient interactions (e.g., reactions between the ingredients affect the acceptability of the final product), ingredients quantities, feasible range of recipe changes, preparation methods, and ingredient constraints due to sensory, regulatory, and cost. The computation platform 111 may store the experimental data in database 113 for future access during the recipe design process.

In one embodiment, the second entity 102 is a non-expert user (e.g., consumers) or a group of non-expert users interacting with a user interface or a web interface of the UE 103 to provide preference information (e.g., flavor preference, product preference, ingredient preference, etc.), health-related information (e.g., food allergies, diabetic, etc.), cultural or religious observances (e.g., religious prohibitions on certain ingredients or products), lifestyle choices (e.g., vegetarian, vegan, etc.), dietary restrictions, nutritional goals, historical purchase data, and so on. In one embodiment, the system 100 may utilize various machine-learning techniques to create hierarchical clusters of users based on preference information, health-related information, cultural or religious observances, lifestyle choices, dietary restrictions, nutritional goals, and/or historical purchase data. In one example, a set of users may be allergic to peanuts, and a different set of users may be allergic to milk. The computation platform 111 may adjust recipes for individual consumers based on allergies or other dietary restrictions. The computation platform 111 may store the user data in database 113 for future access during the recipe design process.

In one embodiment, the UE 103 includes, but is not restricted to, any type of mobile terminal, wireless terminal, fixed terminal, or portable terminal. Examples of the UE 103, include, but are not restricted to, a mobile handset, a wireless communication device, a station, a unit, a device, a multimedia computer, a multimedia tablet, an Internet node, a communicator, a desktop computer, a laptop computer, a notebook computer, a netbook computer, a tablet computer, a Personal Communication System (PCS) device, a personal navigation device, a Personal Digital Assistant (PDA), a digital camera/camcorder, an infotainment system, a dashboard computer, a television device, or any combination thereof, including the accessories and peripherals of these devices, or any combination thereof. Any known and future implementations of the UE 103 are also applicable.

In one embodiment, the applications 105 includes various applications such as, but not restricted to, content provisioning applications, software applications, networking applications, multimedia applications, media player applications, camera/imaging applications, and the like. In one embodiment, one of the applications 105 at the UE 103 acts as a client for computation platform 111 and performs one or more functions associated with the functions of the computation platform 111 by interacting with the computation platform 111 over the communication network 109.

By way of example, each sensor 107 includes any type of sensor. In one embodiment, the sensors 107 include, for example, a network detection sensor for detecting wireless signals or receivers for different short-range communications (e.g., Bluetooth, Wi-Fi, Li-Fi, near field communication (NFC), etc.), a camera/imaging sensor for gathering image data, an audio recorder for gathering audio data, and the like.

In one embodiment, various elements of the system 100 communicate with each other through the communication network 109. The communication network 109 supports a variety of different communication protocols and communication techniques. In one embodiment, the communication network 109 allows the computation platform 111 to communicate with the UE 103 and database 113. The communication network 109 of the system 100 includes one or more networks such as a data network, a wireless network, a telephony network, or any combination thereof. It is contemplated that the data network is any local area network (LAN), metropolitan area network (MAN), wide area network (WAN), a public data network (e.g., the Internet), short range wireless network, or any other suitable packet-switched network, such as a commercially owned, proprietary packet-switched network, e.g., a proprietary cable or fiber-optic network, and the like, or any combination thereof. In addition, the wireless network is, for example, a cellular communication network and employs various technologies including 5G (5th Generation), 4G, 3G, 2G, Long Term Evolution (LTE), wireless fidelity (Wi-Fi), Bluetooth®, Internet Protocol (IP) data casting, satellite, mobile ad-hoc network (MANET), vehicle controller area network (CAN bus), and the like, or any combination thereof.

In one embodiment, the computation platform 111 is a platform with multiple interconnected components. The computation platform 111 include one or more servers, intelligent networking devices, computing devices, components, and corresponding software for generating recipes. The computation platform 111 may process experimental data to determine predicted attributes. In one example, the predicted attributes may include sensory data (e.g., taste, texture, etc.), consumer data (e.g., preference information, purchase intent, etc.), product properties (e.g., moisture, fat content, viscosity, hardness, shelf life stability, etc.), packaging properties (e.g., moisture migration, oxidation, etc.), and processing properties (e.g., production throughput, operating temperature, etc.). The computation platform 111 may integrate the collected data and knowledge for data collection, data reconciliation, data analytics, and data visualization. In one embodiment, the computation platform 111 may utilize various computational technologies (e.g., statistical modeling, first-principle modeling, Artificial Intelligence/Machine-learning algorithms, etc.) to build a predictive model.

In one embodiment, the computation platform 111 includes a data collection module 115, a data processing module 117, a machine-learning module 119, a recommendation module 121, a user interface module 123, or any combination thereof. As used herein, terms such as “component” or “module” generally encompass hardware and/or software, e.g., that a processor or the like is used to implement associated functionality. It is contemplated that the functions of these components are combined in one or more components or performed by other components of equivalent functionality.

In one embodiment, the data collection module 115 may collect relevant data, (e.g., recipe data, user preference data, and/or expert opinions (e.g., ingredient functionality, ingredient interactions, feasible range of recipe changes, ingredient constraints, etc.)) through various data collection techniques. In one example, the data collection module 115 may use a web-crawling component to access various data sources (e.g., recipe websites, forums, food blogs, etc.) to collect relevant data. In one example, the data collection module 115 includes various software applications (e.g., data mining applications in Extensible Markup Language (XML)), that automatically search for and return relevant data. By combining relevant data from various sources, the data collection module 115 may create a comprehensive dataset of recipes.

In one embodiment, the data processing module 117 may process, parse, and arrange data collected by the data collection module 115 into a common format that is easily processed by other modules and platforms. In one example, the data processing module 117 may remove or correct erroneous data (e.g., redundant, incomplete, or incorrect data) to create high-quality data to avoid bias and redundancy in the dataset, promoting diversity in recipe generation. In one example, the data processing module 117 may categorize the relevant data to assist the machine-learning model in recognizing semantic relationships between different components of the recipes, enabling the machine-learning model to generate coherent and realistic combinations.

In one embodiment, the machine-learning module 119 may receive training data (e.g., training data 1212 illustrated in the training flow chart 1200) for training a machine-learning model. The machine-learning module 119 may perform model training using training data (e.g., data from other modules) that contains input and correct output, to allow the model to learn over time. The training is performed based on the deviation of a processed result from a documented result when the inputs are fed into the machine-learning model (e.g., an algorithm measures its accuracy through the loss function, adjusting until the error has been sufficiently minimized). In one example, the machine-learning model may be trained on a large dataset of recipes, learning the sequential patterns and ingredient combinations inherent in the recipes. During the training, the machine-learning model may predict the next step or ingredient given the preceding sequence of instructions or ingredients.

In another embodiment, the machine-learning module 119 may randomize the ordering of the training data, visualize the training data to identify relevant relationships between different variables, identify any data imbalances, and split the training data into two parts where one part is for training a model and the other part is for validating the trained model, de-duplicating, normalizing, correcting errors in the training data, and so on. The machine-learning module 119 may implement various machine-learning techniques, e.g., k-nearest neighbors, cox proportional hazards model, decision tree learning, association rule learning, neural network (e.g., recurrent neural networks, graph convolutional neural networks, deep neural networks), inductive programming logic, support vector machines, Bayesian models, etc. In one instance, the machine-learning models may enable the extraction of intricate patterns and relationships within vast amounts of recipe data, facilitating the creation of novel and innovative recipes that resonate with diverse tastes and preferences. In one instance, the machine-learning models may adapt and improve over time by learning from feedback and evolving culinary trends, ensuring the generated recipes remain up-to-date and relevant.

In one embodiment, the recommendation module 121 may perform various calculations on the processed data to generate probability scores indicating a likelihood of the second entity 102 accepting and using the recipes. In one embodiment, the recommendation module 121 may generate recipe recommendations based on knowledge from subject matter experts and experimental data. For example, the recommendation module 121 may process relevant data (e.g., expert opinion) to determine an optimal recipe with the best ingredients. For example, the recommendation module 121 may process relevant data (e.g., user preference data) to determine a recipe that meets user-defined criteria. In one embodiment, the recommendation module 121 may, via machine-learning models, analyze user behavior, user preferences, and historical data to create personalized recommendations. By learning from past data, the machine-learning models may tailor recommendations to individual users, increasing the likelihood of user satisfaction and engagement. In one embodiment, the recommendation module 121, via machine-learning models, may adapt to changing user preferences and trends. By continuously learning from new data and feedback, the recommendation module 121 may update its algorithm to reflect evolving user interests and preferences, ensuring that recommendations remain relevant.

In one embodiment, the user interface module 123 may enable a presentation of a graphical user interface (GUI) in the UE 103 that facilitates recipe visualization. The user interface module 123 may employ various application programming interfaces (APIs) or other function calls corresponding to the application 105 on the UE 103, thus enabling the display of graphics primitives such as icons, bar graphs, menus, buttons, data entry fields, etc. In one example, the user interface module 123 may cause a display of the recommendations generated by the recommendation module 121 in the UE 103. In one example, the user interface module 123 may cause a presentation of the probability scores calculated by the recommendation module 121 in the UE 103. In one example, the user interface module 123 may present recipe recommendations based on one or more recipes that meet the user-specified threshold requirements in the UE 103.

In one embodiment, the user interface module 123 may cause interfacing of guidance information to include, at least in part, one or more annotations, audio messages, video messages, or a combination thereof pertaining to the generated recipes. In one example, the first entity 101 may interact with the GUI on the UE 103 to input data necessary for generating recipes, and the user interface module 123 may generate various displays of the resulting recipes. In such a manner, the user interface module 123 processes the received data and displays the results in a format that is understandable by the users. In one example, the user interface module 123 may operate in connection with augmented reality (AR) processing techniques, wherein various applications, graphic elements, and features interact.

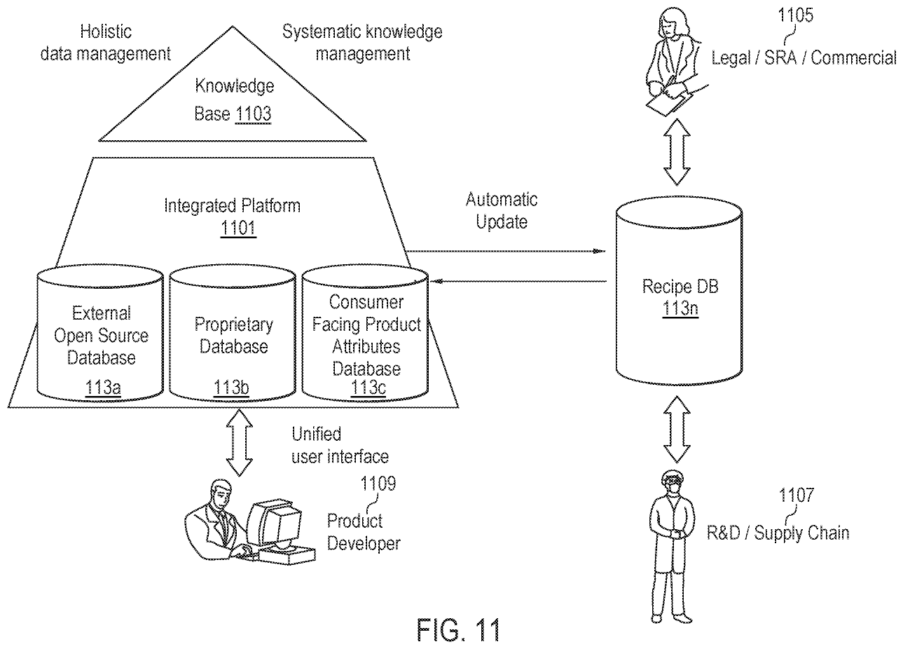

In one embodiment, the computation platform 111 may store newly collected data and/or learnings in database 113 or update the existing knowledge based on the newly collected information from the subject matter experts or experimental data. The knowledge is maintained in the database 113 and utilized by an inference engine (e.g., artificial intelligence or machine-learning model) to assess and generate the recipes. In one embodiment, the database 113 is any type of database, such as relational, hierarchical, object-oriented, and/or the like, wherein data are organized in any suitable manner, including data tables or lookup tables. In one example, database 113 may include recipe database, a user preference database, an expert opinion database, an external open source database 113a, a proprietary database 113b, a consumer-facing product attributes database 113c (as illustrated in FIG. 11), and so on. In one embodiment, the database 113 stores content associated with the UE 103 and the computation platform 111, and manages multiple types of information that provide means for aiding in the content provisioning and sharing process. In one embodiment, the database 113 includes a machine-learning based training database with a pre-defined mapping defining a relationship between various input parameters and output parameters based on various statistical methods. In one example, the training database includes a dataset that includes data collections that are not subject-specific, e.g., data collections based on population-wide observations, local, regional, or super-regional observations, and the like. The training database is routinely updated and/or supplemented based on machine-learning methods.

The above presented modules and components of the computation platform 111 are implemented in hardware, firmware, software, or a combination thereof. Though depicted as a separate entity in FIG. 1, it is contemplated that the computation platform 111 is also implemented for direct operation by the respective UE 103. As such, the computation platform 111 generates direct signal inputs by way of the operating system of the UE 103. In another embodiment, one or more of the modules 115-123 are implemented for operation by the respective UEs, as the computation platform 111. The various executions presented herein contemplate any and all arrangements and models.

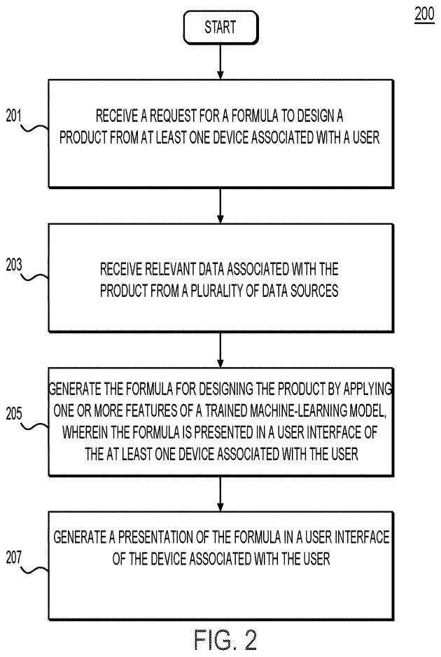

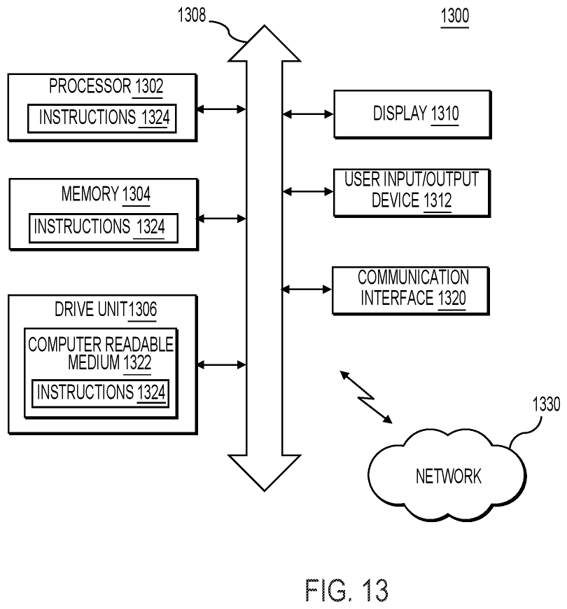

FIG. 2 is a flowchart of a process for recipe engineering in product design, according to aspects of the disclosure. In various embodiments, the computation platform 111 and/or any of the modules 115-123 may perform one or more portions of the process 200 and are implemented using, for instance, a chip set including a processor and a memory as shown in FIG. 13. As such, the computation platform 111 and/or any of modules 115-123 may provide means for accomplishing various parts of the process 200, as well as means for accomplishing embodiments of other processes described herein in conjunction with other components of the system 100. Although the process 200 is illustrated and described as a sequence of steps, it is contemplated that various embodiments of the process 200 may be performed in any order or combination and need not include all of the illustrated steps.

In step 201, the computation platform 111 may receive a request for a formula (e.g., recipe) to design a product from the UE 103 associated with a user (e.g., the second entity 102). Upon receiving the request, the computation platform 111 acknowledges the user's intent to formulate a recipe tailored to a particular product. In one embodiment, the computation platform 111 may present a query in the UE 013 associated with the user for additional information (e.g., preference information, health-related information, or historical data). The computation platform 111 may receive the additional information and may update the formula based on the additional information. In one example, the computation platform 111 may dynamically update the recipe based on user-provided parameters (e.g., flavor preferences, dietary restrictions, nutritional requirements, and past recipe experiences) to align with the specific needs and preference of the user. Continuous refinement of the recipe may occur as the computation platform 111 adapts to evolving user preferences and health considerations over time.

In step 203, the computation platform 111 may receive relevant data associated with the product from a plurality of data sources. In one embodiment, the computation platform 111 may identify one or more properties associated with the ingredients of the product. One or more properties may include physical properties (e.g., texture, color, density, particle size, viscosity of the ingredients, etc.) and/or chemical properties (e.g., solubility, reactivity, melting point, boiling point, toxicity, heat capacity of the ingredients, etc.).

The computation platform 111, via the machine-learning module 119, may extract one or more properties as features for training the machine-learning model.

In one example, the extracted properties may encompass a diverse range of characteristics including ingredient composition, nutritional content, sensory attributes, market trends, and regulatory compliance. In one instance, through advanced data processing techniques, such as feature engineering and dimensionality reduction, the computation platform 111 may identify and extract meaningful patterns and relationships within the data to create a comprehensive feature set for training the machine-learning model.

In one embodiment, the computation platform may utilize a natural language processing (NLP) technique for analyzing textual data from the relevant data associated with the product for extracting meaningful insights and patterns from unstructured text. In one example, the NLP techniques may enable the system to understand and interpret human language, allowing for sentiment analysis, entity recognition, and topic modeling. On the other hand, the computation platform may utilize a network processing algorithm for modeling complex relationships within the relevant data associated with the product. The network processing algorithm may analyze connections and interactions between different data points, enabling it to capture complex patterns and dependencies that may exist among variables.

In step 205, the computation platform 111 may generate the formula for designing the product by applying one or more features of a trained machine-learning model. In one embodiment, the trained machine-learning model is trained by inputting the relevant data associated with the product into the machine-learning model. This process includes feeding the machine-learning model with a diverse range of input parameters, including but not limited to ingredient compositions, nutritional information, sensory attributes, market trends, and preference information. The machine-learning model upon receiving the input data may iteratively learn to discern patterns, correlations, and complex relationships within the dataset.

In one embodiment, the computation platform 111 may employ a supervised learning technique to optimize the machine-learning model through iterative learning algorithms. In one example, the machine-learning model is exposed to labeled datasets containing input-output pairs, allowing it to learn the underlying patterns and relationships within the data. Through iterative adjustments to its parameters based on observed errors, the machine-learning model may gradually improve its predictive capabilities, minimizing discrepancies between predicted and actual outcomes.

In one embodiment, the computation platform 111 may evaluate the performance of the machine-learning model using validation techniques to assess its efficacy. In one example, the validation techniques may include assessing the performance of the machine-learning model on unseen data to ensure that it may effectively generalize to new, unseen examples beyond the training set. By subjecting the model to rigorous validation procedures, the computation platform 111 may gain insight into its ability to accurately predict outcomes and identify potential areas for improvement.

In one embodiment, the computation platform 111 may determine ingredient interaction, ingredient specification, rheological properties, and/or adherence to regulatory standards while generating the formula for the product. In one example, the computation platform 111 may evaluate the compatibility and synergy between ingredients to optimize the flavor profiles, texture, and overall product quality. The computation platform 111 may specify precise quantities, measurements, and characteristics of each ingredient to maintain consistency in the recipe formulations. The computation platform 111 may also consider the rheological properties of ingredients, such as viscosity and elasticity, to tailor cooking techniques to achieve the desired texture of the product. The computation platform 111 may enforce adherence to regulatory standards and guidelines to ensure product safety, legality, and compliance. By integrating these considerations into the recipe generation workflow, the computation platform 111 may ensure that the generated recipes meet quality standards and regulatory requirements.

In one embodiment, the computation platform 111 may analyze external data (e.g., molecular structure, chemical composition, physical properties of ingredients associated with the product, etc.), proprietary data (e.g., ingredient composition and property information, processing knowledge, quantifiable product properties, etc.), and consumer-facing product attributes (e.g., distinctive product attributes, pass/fail criteria for the formula and the product, consumer liking correlation to revenue potential, etc.). The computation platform 111 may identify one or more connections between the external data, the proprietary data, and the consumer-facing product attributes to predict product outcomes. By analyzing the interrelationships between these diverse datasets, the computation platform 111 may uncover hidden patterns, correlations, and causal relationships that influence product outcomes. The computation platform 111 may update, via the machine-learning model, the formula upon determining new content or updates based on the external data, the proprietary data, and the consumer-facing product attributes. This dynamic process ensures that the recipe remains current and aligned with the latest market trends and consumer preferences. By leveraging real-time insights from diverse data sources, the recipe may be interactively refined to optimize taste and quality.

In one embodiment, the computation platform 111 may evaluate the performance of the product resulting from the formula, wherein the performance of the product is based on taste, texture, appearance, and user satisfaction. In one example, through sensory testing, consumer feedback, and product testing methodologies, the computation platform 111 may gather valuable insights into the product's overall quality and consumer acceptance. These assessment provide crucial feedback on the effectiveness of the recipe formulation and identify areas for improvement. The computation platform 111 may update the training data for training the machine-learning model based on the evaluated product performance data. By iteratively refining the training data based on real-world product evaluation, the computation platform 111 may enhance the predictive accuracy of the machine-learning model and its ability to generate recipes that meet quality standards and consumer expectations.

In one embodiment, the computation platform 111 may determine environmental impact associated with a production process for the product based on the formula. The environmental impact may include one or more of carbon footprint, water usage, waste generation, and energy consumption. By analyzing the data related to ingredients sourcing, and manufacturing methods, the computation platform 111 may quantify the ecological footprint of the production process. The computation platform 111 may update training data for training the machine-learning model for prioritizing ingredient and production methods that minimize the environmental impact. This enables the machine-learning model to learn from past environmental assessments and prioritize sustainable practices in recipe formulations.

In step 207, the computation platform 111 may generate a presentation of the formula in UE 103 associated with the user (e.g., the second entity 102). In one instance, the recipe may be presented in a visually appealing format, providing step-by-step instructions.

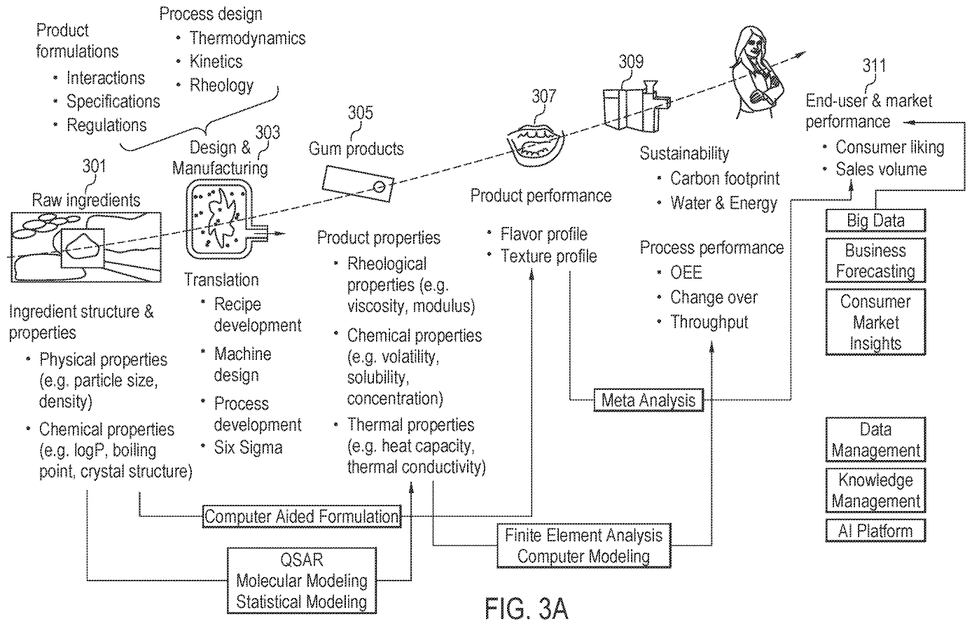

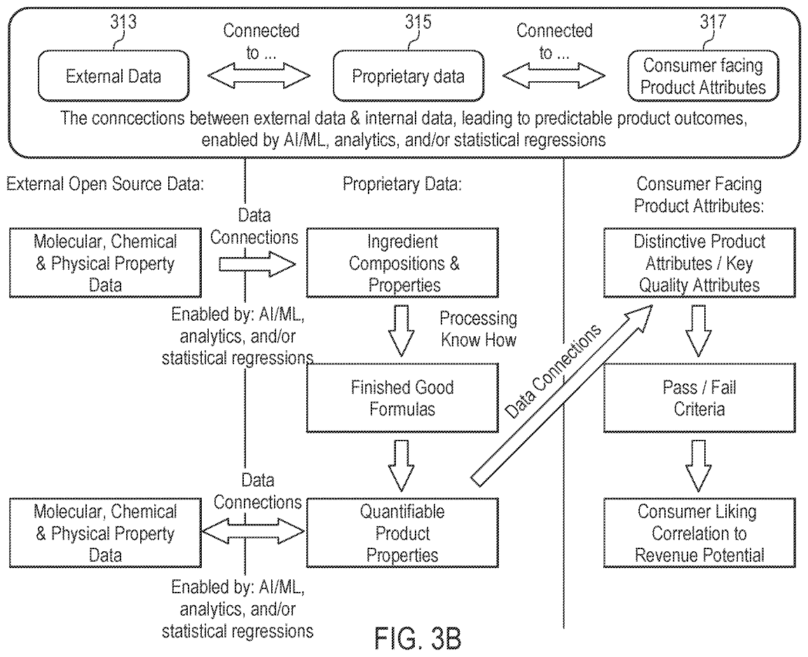

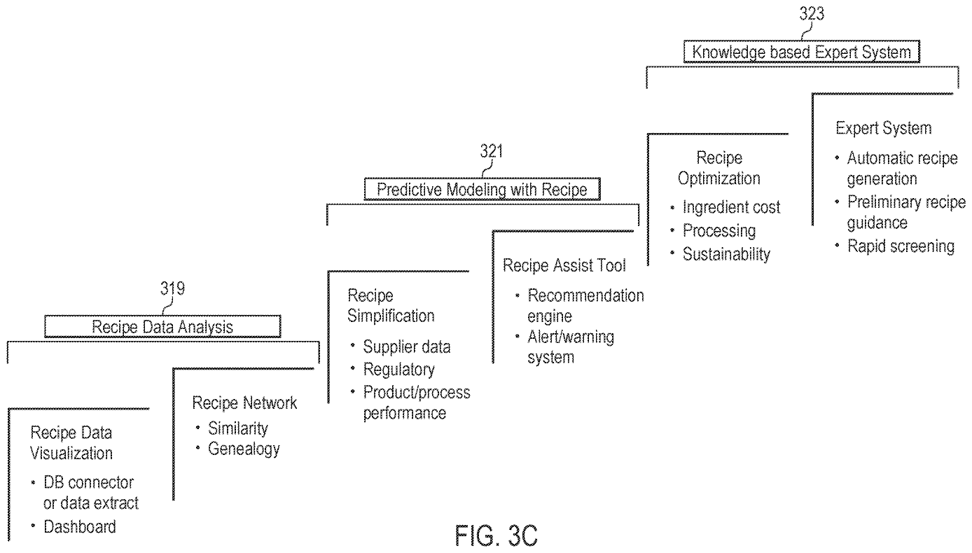

FIG. 3A is a flow diagram that illustrates the stages and elements involved in the lifecycle of a product, according to aspects of the disclosure. In step 301, the computation platform 111 may determine ingredient structure and properties (e.g., physical properties and chemical properties) associated with a product. In one example, the physical properties may include observable characteristics such as particle size, density, color, and/or texture providing insights into how the ingredients behave under various conditions. In one example, the chemical properties may include boiling point, crystal structure, and/or ingredient reactivity shedding light on the potential reaction of the ingredients with other substances and their suitability for specific application.

In step 303, the computation platform 111 may design the recipe and manufacture the product (e.g., chewing gum). In one instance, the computation platform 111 may determine ingredient interaction, precise specifications, and adherence to regulatory standards to ensure safety and quality during product formulations. In one instance, the computation platform 111 may optimize thermodynamic conditions, understand reaction kinetics, and manage rheological properties for efficient production and consistent product quality during process designs. In one instance, the design and manufacturing process may also include recipe development, machine designs, and process development.

In step 305, the computation platform 111 may determine product properties (e.g., rheological properties, chemical properties, thermal properties) for understanding the behavior and characteristics of the product across various conditions. In one example, rheological properties may include viscosity and elasticity that provide insights into the flow behavior and structural stability of the product. In one example, chemical properties may include volatility, solubility, and concentration information to help identify the reactivity of the product with its environment. In one example, thermal properties may include heat capacity and thermal conductivity to indicate the product's response to temperature changes, impacting its stability, processing, and storage.

In step 307, the computation platform 111 may evaluate product performance (e.g., flavor profile, texture profile, etc.) to assess the quality of the product. In one example, flavor profile delve into the nuances of taste, identifying primary flavors, aroma, and aftertaste. In one example, texture profile assessment focuses on factors like mouthfeel, chewiness, and crispness.

In step 309, the computation platform 111 may determine the sustainability and process performance of the product. In one example, sustainability considerations revolve around environmental impact factors, such as carbon footprint, water usage, and energy consumption. These metrics provide insight into the ecological footprint of the production process, allowing for the identification of areas for improvement and optimization to minimize environmental harm. In one example, evaluating process performance may include metrics, such as overall equipment effectiveness (OEE), changeover times, and throughout rates. OEE may offer a holistic view of equipment efficiency, factoring in availability, performance, and quality metrics. Changeover times may gauge the agility and flexibility of the production line, while throughput rates may measure the quantity of output over a specific time period.

In step 311, the computation platform 111 may determine end-user and market performance for business forecasting and consumer market insights. In one example, the computation platform 111 may evaluate consumer liking through surveys, reviews, and feedback mechanisms to determine product acceptance, taste preference, and potential areas for improvement. In one example, the computation platform 111 may evaluate sales volume to quantify the commercial success of the product, reflecting its popularity and demand in the market. The computation platform 111 may accurately forecast trends and anticipate demand fluctuations. As illustrated, one or more steps of FIG. 3A may be performed using computer-aided formulation, quantitative structure-activity relationship (QSAR), molecular modeling, statistical modeling, finite element analysis, computer modeling, and/or meta-analysis.

FIG. 3B illustrates an integrated data-driven approach to product development, according to aspects of the disclosure. In one embodiment, the computation platform 111, via machine-learning module 119, may determine a connection between external data 313, proprietary data 315, and consumer-facing product attributes 317 to predict product outcomes.

In one instance, the external data 313 may include external open-source data on the molecular structure of the ingredients, their chemical composition, and physical properties such as melting points, viscosity, and crystallization behavior.

In one instance, the proprietary data 315 may include ingredients used, their composition, and specific properties relevant to the production process. In one example, the proprietary data 315 may include specific formulations and recipes used in the manufacturing process, including ingredient proportions and processing steps. In one example, the proprietary data 315 may include quantifiable product properties such as texture, shelf-life, and sensory attributes (e.g., taste, aroma, appearance) that define the quality of the finished product.

In one instance, the consumer-facing product attributes 317 may include distinctive product attributes, pass/fail criteria, and consumer liking correlation to revenue potential. In one example, distinctive product attributes are characteristics that consumers (e.g., second entity 102) perceive and evaluate when making purchasing decisions. For chocolates, the attributes may include taste profile (sweetness level, flavor combinations), texture (chewy, crunchy), appearance (color, shape), packaging, and branding. In one example, pass/fail criteria determine whether a product meets quality standards or regulatory requirements. In one example, by understanding consumer preferences relate to revenue potential and leveraging this insight to guide product development. As illustrated, computation platform 111 may utilize artificial intelligence, machine-learning models, data analytics, and/or statistical regressions during this integrated data-driven approach.

FIG. 3C illustrates a computer-guided recipe generation process, according to aspects of the disclosure. In step 319, the computation platform 111 may perform recipe data analysis. In one instance, the recipe data analysis may include extracting recipe data utilizing a database connector or data extraction tool and employing various visualization techniques for understanding the underlying patterns and structures within the extracted recipe data. In one example, various visualization methods may be utilized, such as scatter plots for ingredient distribution, histograms for ingredient frequencies, and heatmaps for ingredient correlations. These visualizations provide insights into ingredient relationships and popular combinations. Additionally, constructing a recipe network may allow for the exploration of recipe similarities and genealogy. By leveraging techniques like graph theory and network analysis, recipes can be represented as nodes, with edges indicating similarities based on ingredient overlap or recipe adaptation. This network-based approach enables the identification of recipe clusters and the discovery of influential recipes.

In step 321, the computation platform 111 may perform predictive modeling in recipe simplification and recipe assist tools. In recipe simplification, predictive modeling leverages supplier data, regulatory requirements, and historical product/process performance to streamline recipes by identifying optimal ingredient substitutions, adjusting quantities for cost-effectiveness, and ensuring compliance with safety and quality standards. On the other hand, the recipe assist tools may employ predictive modeling techniques, such as recommendation engines and alert warnings to assist in real-time recipe creation and modification. In one example, the recipe assist tools may analyze user preferences, ingredient availability, and contextual factors to suggest recipe variations, alerts about potential quality issues, and anticipate production challenges, thereby enhancing productivity.

In step 323, the computation platform 111 may provide a knowledge-based expert system. In one instance, the knowledge-based expert system integrates recipe optimization factors in ingredient cost and processing sustainability, employing algorithms to minimize expenses while maximizing environmental friendliness. This entails sourcing ingredients economically, considering bulk purchase options, and selecting processing methods that reduce energy consumption and waste generation. In one instance, the knowledge-based expert system integrates an expert system that encompasses automatic recipe generation, offering diverse recipes tailored to user preferences and dietary restrictions. It also provides preliminary recipe guidance, offering suggestions and substitutions based on available ingredients or user preferences. Furthermore, the expert system facilitates rapid screening of recipes, swiftly evaluating their nutritional content, taste profiles, and production feasibility.

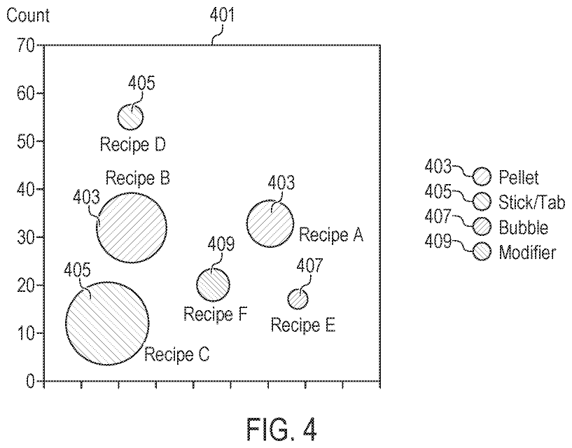

FIG. 4 illustrates production volume by recipe and factory, according to aspects of the disclosure. In one embodiment, the computation platform 111 may compile a comprehensive dataset containing information on production volumes, and details on recipes and the factories where they are produced. Each entry in the dataset may represent a specific production batch recording the recipe used, the quantity produced, and the factory responsible. The computation platform 111 may utilize this data to generate, via the user interface module 123, a bubble chart 401 depicting the production volume for a product (e.g., chewing gum) in the UE 103. In bubble chart 401, each bubble (e.g., 403 through 409) may represent a specific recipe produced at a particular factory, with the size of the bubble corresponding to the production volume. In one example, each bubble pattern may depict details about the product type (e.g., 403 indicates pellet gum, 405 indicates stick/tab gum, 407 indicates bubblegum, and 409 indicates modifier gum). Such visual representation may provide a clear overview of production volumes for each recipe, as well as insights into production distribution among different factories, facilitating analysis and decision-making processes related to production optimization and resource allocation.

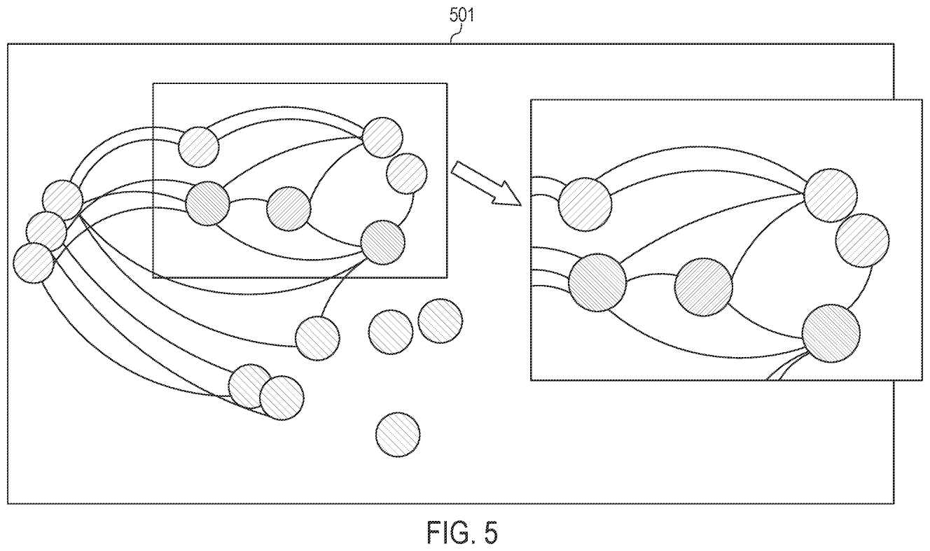

FIG. 5 is a diagram that illustrates a recipe network, according to aspects of the disclosure. In one instance, the computation platform 111 may cause a display, via user interface module 123, of bubble graph 501 in a user interface the UE 103. In one example, the bubble graph 501 may represent a recipe network that visualizes the relationship between various recipes, and connections between the recipes are represented by lines (edges) linking related recipes. These connections may be based on ingredients, cooking methods, flavors, or any other relevant criteria. The size of each bubble may represent the popularity or complexity of the recipe, while the distance between the bubbles may indicate their similarity or relatedness. In one example, the recipe network may depict genealogy and connections between recipes by visually showing how recipes are related to each other. For example, a bubble representing a classic recipe for “chocolate” may be connected to a bubble representing variations like “gluten-free chocolate”. In some embodiments, the recipes may be extracted from documents that describe the recipes, such as, e.g., publications, patents, or any other literature or document that provides information pertaining to various recipes. Text mining techniques may be applied to extract recipes from the documents, and once extracted the recipes are organized and structured in a format suitable for analysis and visualization within the recipe network. The depiction of the recipe network is illustrative and may be presented in any other format.

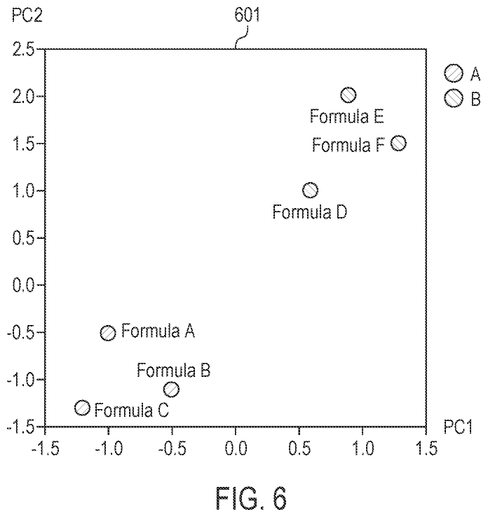

FIG. 6 illustrates a graph for recipe simplification, according to aspects of the disclosure. In one embodiment, the computation platform 111 may cause a display, via user interface module 123, of chart 601 in the UE 103. The chart 601 may show recipe similarity based on principal component analysis (PCA). In one embodiment, the computation platform 111 may apply PCA to reduce the dimensionality of the feature space while preserving the variance in the data. PCA may identify the principal components that best represent the variability in the recipes. The computation platform 111 may calculate the similarity between recipes based on their reduced dimensional representations. This may include calculating distances (e.g., Euclidean distance) or similarities (e.g., cosine similarity) between the PCA-transformed recipe vectors. The chart 601 may visualize the recipe similarity matrix, wherein similar recipes may be clustered together facilitating the identification of common ingredients and flavor profiles. This simplification process aids in understanding recipe relationships, guiding the creation of new recipes, and optimizing ingredients usage for efficiency and flavor balance.

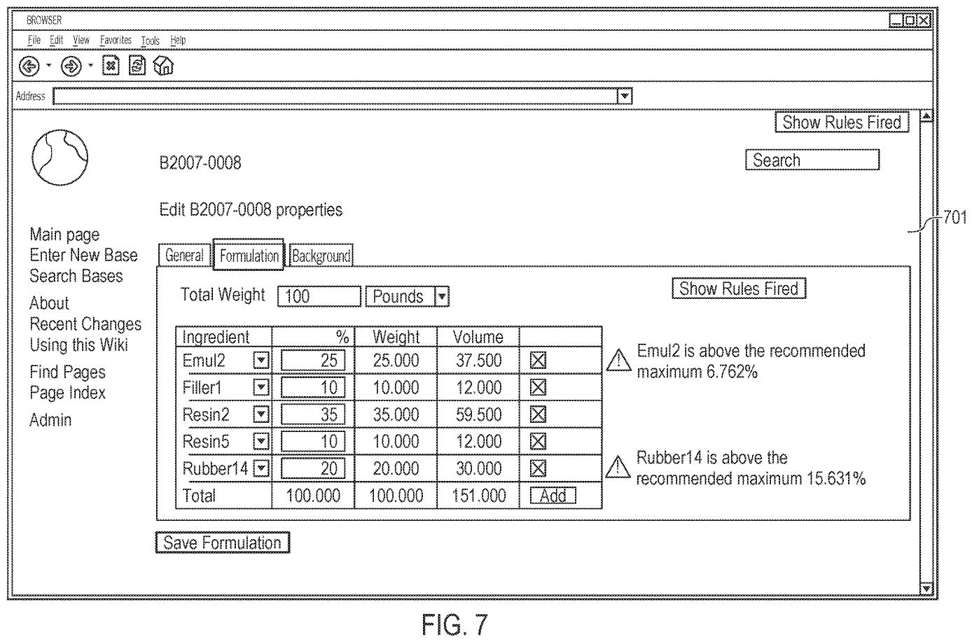

FIG. 7 is a user interface diagram that illustrates a real-time recipe alert, according to aspects of the disclosure. In one embodiment, the computation platform 111 may cause a display, via user interface module 123, of user interfaces in the UE 103. In one example, the user interfaces may ask various questions to the second entity 102 (e.g., what country is the product for? what is the flavor profile? how much sugar can/should it have? etc.) In one example, the user interfaces may include interface 701 which may ask the second entity 102 to enter weight information or volume information for one or more ingredients of a recipe. The second entity 102 may be alerted, in real-time or near real-time, if the entered weight information or volume information exceeds the recommended threshold level, ensuring adherence to safety and quality standards. In one instance, the recommended threshold level may be determined based on industry standards, nutritional guidelines, and expert knowledge to ensure optimal safety and quality for a product. As illustrated in FIG. 7, the second entity 102 is notified that the weight information and/or volume information for certain ingredients (e.g., Emul2 and Rubber 14) are above the threshold level. By leveraging this interface, experts can deliver personalized assistance and enhance the overall production process.

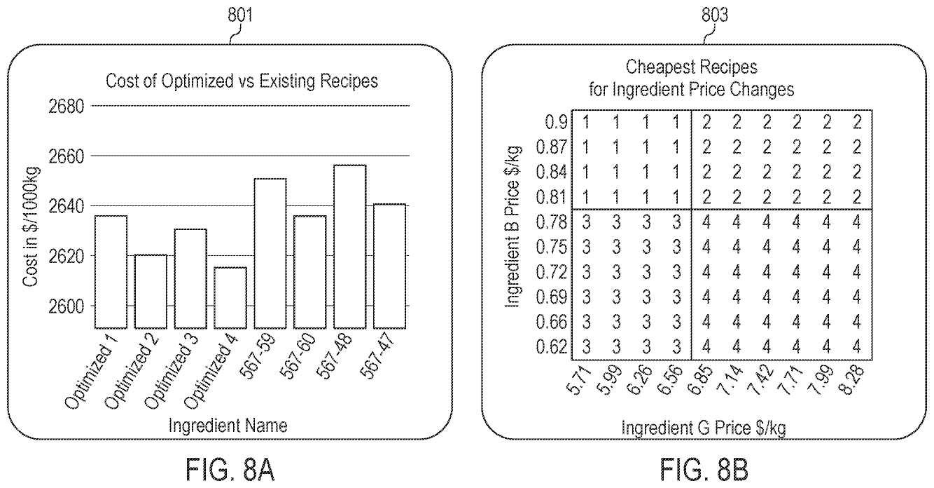

FIGS. 8 A-B are graph diagrams that illustrate recipe optimization, according to aspects of the disclosure. In one embodiment, the computation platform 111 may cause a display, via user interface module 123, of graphs 801 and 803 in the UE 103. In one example, the graph 801 of FIG. 8A plots optimized recipes and existing recipes with their respective costs. By juxtaposing the optimized recipe's ingredients and costs against those of existing recipes, stakeholders may swiftly identify areas for improvement and cost-saving opportunities. For example, the graph 801 compares the cost of the optimized recipes 1, 2, 3, and 4 against the cost of the existing recipes (e.g., 567-59, 567-60, 567-48, and 567-47). This visualization not only highlights the economic advantages of optimizing recipes but also facilitates data-driven decision-making in recipe development.

In one example, the graph 803 of FIG. 8B visualizes the impact of ingredient price changes on recipe affordability, with the x-axis representing the price of ingredient G and the y-axis representing the price of ingredient B. As ingredient prices fluctuate, the chart dynamically adjusts to demonstrate the points at which ingredient B becomes a more cost-effective option for the recipe compared to ingredient G. For example, if the price for ingredient B changed to $0.84 and the price for ingredient G changed to $6.28, then recipe 1 may be the cheapest compared to recipes 2, 3, and 4.

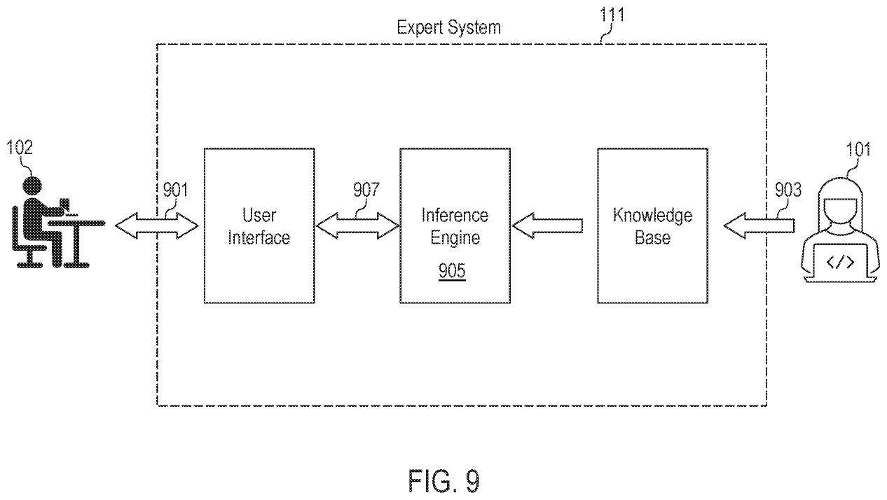

FIG. 9 illustrates an expert system for providing advice to non-expert users, according to aspects of the disclosure. In step 901, the computation platform 111 (also known as the expert system), via user interface module 123, may generate a presentation in the UE 103 (e.g., user interface 701 of FIG. 7), requesting information from the second entity 102. The second entity 102 may interact with the user interface to provide the requested information, such as the country the product is sold, flavor profile for the product, sugar content, and/or preference information. In step 903, the computation platform 111 may receive, via the data collection module 115, expert data from first entity 101 (e.g., ingredient functionality, ingredient interactions, feasible range of recipe changes, and ingredient constraints due to sensory, regulatory, and cost). In one embodiment, the inference engine 905 of the computation platform 111 may process the received data (e.g., from steps 901 and 903) to generate a tailored recommendation, providing the second entity 102 with optimized suggestions for their recipes. In step 907, the tailored recommendation may be presented in the UE 103 associated with the second entity 102.

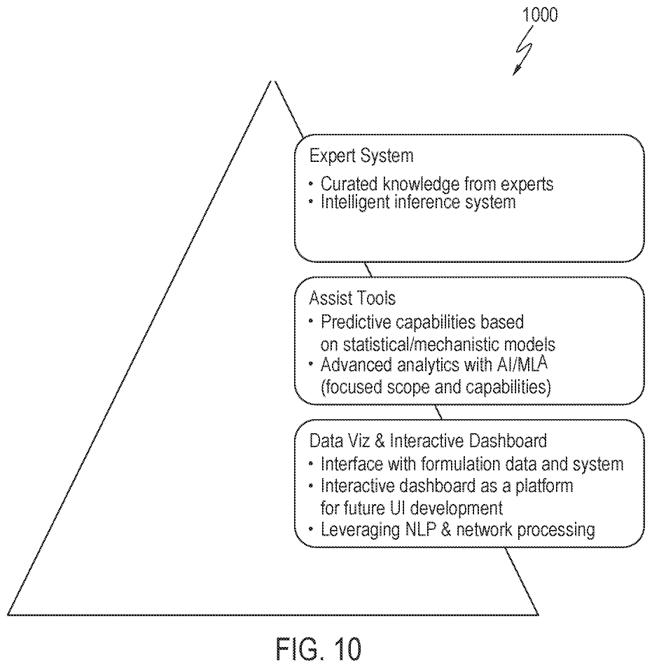

FIG. 10 illustrates a building block for computer-guided recipe generation, according to aspects of the disclosure. In one example, graph 1000 discloses an expert system that is built upon a knowledge base curated from experts in the field, which contains rules, facts, and heuristics relevant to recipe generation. The expert system utilizes an intelligent inference engine (e.g., inference engine 905 of FIG. 9) to reason and make decisions based on the knowledge stored in the knowledge base. In a chocolate recipe scenario, the inference engine may suggest ingredient substitution, cooking times, or flavor adjustments based on the input provided by the user.

In one example, graph 1000 discloses an assist tool that leverages predictive models based on statistical or mechanistic principles to provide insights or forecasts related to recipe generation. In the context of candy making, these models may predict factors such as candy textures, shelf life, or sensory attributes based on input parameters such as ingredients, processing conditions, and/or storage environment. The assist tool may employ artificial intelligence/machine-learning to analyze data and extract actionable insights.

In one example, graph 1000 discloses a data visualization and interactive dashboard. In one embodiment, the computation platform 111 may provide a dashboard for the second entity 102 to interact with formulation data, including recipes, ingredients specification, and process parameters. The second entity 102 may input their requirements or preferences, and the computation platform 111 may generate relevant insights or recommendations in the dashboard. The dashboard presents data visualization tools and interactive features to facilitate data exploration, analysis, and decision-making. In one instance, natural language processing (NLP) techniques may be employed to interpret and analyze textual data, such as user queries or feedback. Additionally, network processing algorithms may be used to model complex relationships or networks within the data, enabling the discovery of hidden insights.

FIG. 11 illustrates a schematic structure for a computer-guided recipe generation process, according to aspects of the disclosure. In one embodiment, the computation platform 111 may provide an integrated platform 1101 that may include the external open source database 113a, the proprietary database 113b, and the consumer-facing product attributes database 113c. In one example, the external open source database 113a may include molecular, chemical, and/or physical property data of one or more ingredients of one or more recipes. In one example, the proprietary database 113b may include ingredient composition and property information, processing knowledge, formula for finished products, and/or quantifiable product properties. In one example, the consumer-facing product attributes database 113c may include distinctive product attributes/key quality attributes, pass/fail criteria for recipes and products, and/or consumer liking correlation to revenue potential. By leveraging the diverse datasets the computation platform 111 may ensure comprehensive data coverage and robust analysis.

In one embodiment, the computation platform 111 may perform holistic data management and/or systematic knowledge management by integrating the knowledge base 1103 of the first entity 101 with the various databases (e.g., the external open source database 113a, the proprietary database 113b, the consumer-facing product attributes database 113c). This integration ensures that the second entity 102 have access to a rich repository of information, enabling them to derive deeper insights, make data-driven decisions, and drive innovation.

In one embodiment, the computation platform 111 may utilize the knowledge base 1103 to add content to the databases or update the databases. In one example, the computation platform 111 may automatically update, in real-time or near real-time, the recipe database 113n upon determining new contents or updates to the external open source database 113a, the proprietary database 113b, and the consumer-facing product attributes database 113c. In another example, the computation platform 111 may automatically update, in real-time or near real-time, the recipe database 113n upon receiving new contents or updates from legal, security risk and assurance (SRA), or commercial entity 1105 or R&D and supply chain entity 1107. The computation platform 111 may generate, via user interface module 123, a presentation of a unified user interface in the UE 103 associated with product developer 1109 (e.g., the second entity 102). In one example, the unified user interface may provide access to diverse databases and knowledge bases within a single environment. The interface may present customizable dashboards, allowing the product developer 1109 to configure views tailored to their specific needs, such as data analysis, trend monitoring, or knowledge discovery. Overall, the unified user interface may prioritize usability, accessibility, and efficiency, empowering the product developer 1109 to leverage the full capabilities of the integrated platform 1101 in their work.

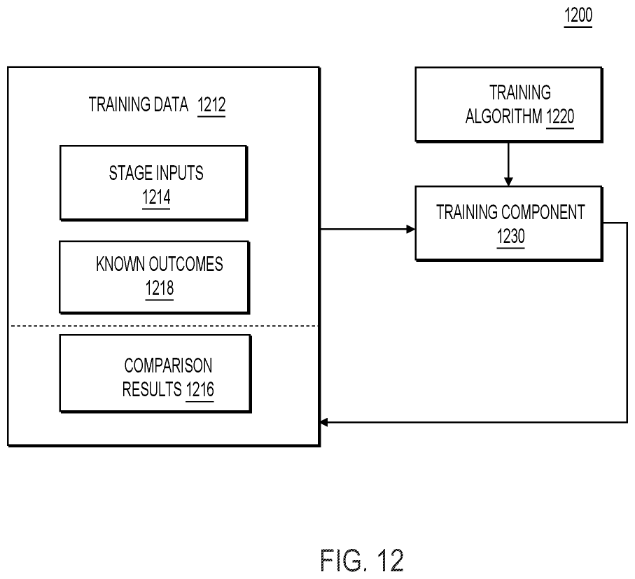

One or more implementations disclosed herein include and/or are implemented using a machine-learning model. For example, one or more of the modules of the computation platform 111 are implemented using a machine-learning model and/or are used to train the machine-learning model. A given machine-learning model is trained using the training flow chart 1200 of FIG. 12. Training data 1212 includes one or more of stage inputs 1214 and known outcomes 1218 related to the machine-learning model to be trained. Stage inputs 1214 are from any applicable source including text, visual representations, data, values, comparisons, and stage outputs, e.g., one or more outputs from one or more steps from FIG. 2. The known outcomes 1218 are included for the machine-learning models generated based on supervised or semi-supervised training. An unsupervised machine-learning model may not be trained using known outcomes 1218. Known outcomes 1218 includes known or desired outputs for future inputs similar to or in the same category as stage inputs 1214 that do not have corresponding known outputs.

The training data 1212 and a training algorithm 1220, e.g., one or more of the modules implemented using the machine-learning model and/or are used to train the machine-learning model, is provided to a training component 1230 that applies the training data 1212 to the training algorithm 1220 to generate the machine-learning model. According to an implementation, the training component 1230 is provided comparison results 1216 that compare a previous output of the corresponding machine-learning model to apply the previous result to re-train the machine-learning model. The comparison results 1216 are used by training component 1230 to update the corresponding machine-learning model. The training algorithm 1220 utilizes machine-learning networks and/or models including, but not limited to a deep learning network such as Deep Neural Networks (DNN), Convolutional Neural Networks (CNN), Fully Convolutional Networks (FCN) and Recurrent Neural Networks (RCN), probabilistic models such as Bayesian Networks and Graphical Models, classifiers such as K-Nearest Neighbors, and/or discriminative models such as Decision Tree and Random Forest and maximum margin methods, the model specifically discussed herein, or the like.

The machine-learning model used herein is trained and/or used by adjusting one or more weights and/or one or more layers of the machine-learning model. For example, during training, a given weight is adjusted (e.g., increased, decreased, removed) based on training data or input data. Similarly, a layer is updated, added, or removed based on training data/and or input data. The resulting outputs are adjusted based on the adjusted weights and/or layers.

In general, any process or operation discussed in this disclosure is understood to be computer-implementable, such as the processes illustrated in FIG. 2 are performed by one or more processors of a computer system as described herein. A process or process step performed by one or more processors is also referred to as an operation. The one or more processors are configured to perform such processes by having access to instructions (e.g., software or computer-readable code) that, when executed by one or more processors, cause one or more processors to perform the processes. The instructions are stored in a memory of the computer system. A processor is a central processing unit (CPU), a graphics processing unit (GPU), or any suitable type of processing unit.

A computer system, such as a system or device implementing a process or operation in the examples above, includes one or more computing devices. One or more processors of a computer system are included in a single computing device or distributed among a plurality of computing devices. One or more processors of a computer system are connected to a data storage device. A memory of the computer system includes the respective memory of each computing device of the plurality of computing devices.

FIG. 13 illustrates an implementation of a computer system that executes techniques presented herein. The computer system 1300 includes a set of instructions that are executed to cause the computer system 1300 to perform any one or more of the methods or computer based functions disclosed herein. The computer system 1300 operates as a standalone device or is connected, e.g., using a network, to other computer systems or peripheral devices.

Unless specifically stated otherwise, as apparent from the following discussions, it is appreciated that throughout the specification, discussions utilizing terms such as “processing,” “computing,” “calculating,” “determining”, analyzing” or the like, refer to the action and/or processes of a computer or computing system, or similar electronic computing device, that manipulate and/or transform data represented as physical, such as electronic, quantities into other data similarly represented as physical quantities.

In a similar manner, the term “processor” refers to any device or portion of a device that processes electronic data, e.g., from registers and/or memory to transform that electronic data into other electronic data that, e.g., is stored in registers and/or memory. A “computer,” a “computing machine,” a “computing platform,” a “computing device,” or a “server” includes one or more processors.

In a networked deployment, the computer system 1300 operates in the capacity of a server or as a client user computer in a server-client user network environment, or as a peer computer system in a peer-to-peer (or distributed) network environment. The computer system 1300 is also implemented as or incorporated into various devices, such as a personal computer (PC), a tablet PC, a set-top box (STB), a personal digital assistant (PDA), a mobile device, a palmtop computer, a laptop computer, a desktop computer, a communications device, a wireless telephone, a land-line telephone, a control system, a camera, a scanner, a facsimile machine, a printer, a pager, a personal trusted device, a web appliance, a network router, switch or bridge, or any other machine capable of executing a set of instructions (sequential or otherwise) that specify actions to be taken by that machine. In a particular implementation, the computer system 1300 is implemented using electronic devices that provide voice, video, or data communication. Further, while the computer system 1300 is illustrated as a single system, the term “system” shall also be taken to include any collection of systems or sub-systems that individually or jointly execute a set, or multiple sets, of instructions to perform one or more computer functions.

As illustrated in FIG. 13, the computer system 1300 includes a processor 1302, e.g., a central processing unit (CPU), a graphics processing unit (GPU), or both. The processor 1302 is a component in a variety of systems. For example, the processor 1302 is part of a standard personal computer or a workstation. The processor 1302 is one or more processors, digital signal processors, application specific integrated circuits, field programmable gate arrays, servers, networks, digital circuits, analog circuits, combinations thereof, or other now known or later developed devices for analyzing and processing data. The processor 1302 implements a software program, such as code generated manually (i.e., programmed).

The computer system 1300 includes a memory 1304 that communicates via bus 1308. Memory 1304 is a main memory, a static memory, or a dynamic memory. Memory 1304 includes, but is not limited to computer-readable storage media such as various types of volatile and non-volatile storage media, including but not limited to random access memory, read-only memory, programmable read-only memory, electrically programmable read-only memory, electrically erasable read-only memory, flash memory, magnetic tape or disk, optical media and the like. In one implementation, the memory 1304 includes a cache or random-access memory for the processor 1302. In alternative implementations, the memory 1304 is separate from the processor 1302, such as a cache memory of a processor, the system memory, or other memory. Memory 1304 is an external storage device or database for storing data. Examples include a hard drive, compact disc (“CD”), digital video disc (“DVD”), memory card, memory stick, floppy disc, universal serial bus (“USB”) memory device, or any other device operative to store data. The memory 1304 is operable to store instructions executable by the processor 1302.

The functions, acts, or tasks illustrated in the figures or described herein are performed by processor 1302 executing the instructions stored in memory 1304.

The functions, acts, or tasks are independent of the particular type of instruction set, storage media, processor, or processing strategy and are performed by software, hardware, integrated circuits, firmware, micro-code, and the like, operating alone or in combination. Likewise, processing strategies include multiprocessing, multitasking, parallel processing, and the like.

As shown, the computer system 1300 further includes a display 1310, such as a liquid crystal display (LCD), an organic light emitting diode (OLED), a flat panel display, a solid-state display, a cathode ray tube (CRT), a projector, a printer or other now known or later developed display device for outputting determined information. The display 1310 acts as an interface for the user to see the functioning of the processor 1302, or specifically as an interface with the software stored in the memory 1304 or in the drive unit 1306.

Additionally or alternatively, the computer system 1300 includes an input/output device 1312 configured to allow a user to interact with any of the components of the computer system 1300. The input/output device 1312 is a number pad, a keyboard, a cursor control device, such as a mouse, a joystick, touch screen display, remote control, or any other device operative to interact with the computer system 1300.

The computer system 1300 also includes the drive unit 1306 implemented as a disk or optical drive. The drive unit 1306 includes a computer-readable medium 1322 in which one or more sets of instructions 1324, e.g. software, is embedded. Further, the sets of instructions 1324 embodies one or more of the methods or logic as described herein. Instructions 1324 resides completely or partially within memory 1304 and/or within processor 1302 during execution by the computer system 1300. The memory 1304 and the processor 1302 also include computer-readable media as discussed above.

In some systems, computer-readable medium 1322 includes the set of instructions 1324 or receives and executes the set of instructions 1324 responsive to a propagated signal so that a device connected to network 1330 communicates voice, video, audio, images, or any other data over network 1330. Further, the sets of instructions 1324 are transmitted or received over the network 1330 via the communication port or interface 1320, and/or using the bus 1308. The communication port or interface 1320 is a part of the processor 1302 or is a separate component. The communication port or interface 1320 is created in software or is a physical connection in hardware. The communication port or interface 1320 is configured to connect with the network 1330, external media, display 1310, or any other components in the computer system 1300, or combinations thereof. The connection with network 1330 is a physical connection, such as a wired Ethernet connection, or is established wirelessly as discussed below. Likewise, the additional connections with other components of the computer system 1300 are physical connections or are established wirelessly. Network 1330 alternatively be directly connected to the bus 1308.

While the computer-readable medium 1322 is shown to be a single medium, the term “computer-readable medium” includes a single medium or multiple media, such as a centralized or distributed database, and/or associated caches and servers that store one or more sets of instructions. The term “computer-readable medium” also includes any medium that is capable of storing, encoding, or carrying a set of instructions for execution by a processor or that causes a computer system to perform any one or more of the methods or operations disclosed herein. The computer-readable medium 1322 is non-transitory, and may be tangible.

The computer-readable medium 1322 includes a solid-state memory such as a memory card or other package that houses one or more non-volatile read-only memories. The computer-readable medium 1322 is a random-access memory or other volatile re-writable memory. Additionally or alternatively, the computer-readable medium 1322 includes a magneto-optical or optical medium, such as a disk or tapes or other storage device to capture carrier wave signals such as a signal communicated over a transmission medium. A digital file attachment to an e-mail or other self-contained information archive or set of archives is considered a distribution medium that is a tangible storage medium. Accordingly, the disclosure is considered to include any one or more of a computer-readable medium or a distribution medium and other equivalents and successor media, in which data or instructions are stored.

In an alternative implementation, dedicated hardware implementations, such as application specific integrated circuits, programmable logic arrays, and other hardware devices, is constructed to implement one or more of the methods described herein. Applications that include the apparatus and systems of various implementations broadly include a variety of electronic and computer systems. One or more implementations described herein implement functions using two or more specific interconnected hardware modules or devices with related control and data signals that are communicated between and through the modules, or as portions of an application-specific integrated circuit. Accordingly, the present system encompasses software, firmware, and hardware implementations.

Computer system 1300 is connected to network 1330. Network 1330 defines one or more networks including wired or wireless networks. The wireless network is a cellular telephone network, an 802.10, 802.16, 802.20, or WiMAX network. Further, such networks include a public network, such as the Internet, a private network, such as an intranet, or combinations thereof, and utilizes a variety of networking protocols now available or later developed including, but not limited to TCP/IP based networking protocols. Network 1330 includes wide area networks (WAN), such as the Internet, local area networks (LAN), campus area networks, metropolitan area networks, a direct connection such as through a Universal Serial Bus (USB) port, or any other networks that allows for data communication. Network 1330 is configured to couple one computing device to another computing device to enable communication of data between the devices. Network 1330 is generally enabled to employ any form of machine-readable media for communicating information from one device to another. Network 1330 includes communication methods by which information travels between computing devices. Network 1330 is divided into sub-networks. The sub-networks allow access to all of the other components connected thereto or the sub-networks restrict access between the components. Network 1330 is regarded as a public or private network connection and includes, for example, a virtual private network or an encryption or other security mechanism employed over the public Internet, or the like.

In accordance with various implementations of the present disclosure, the methods described herein are implemented by software programs executable by a computer system. Further, in an example, non-limited implementation, implementations can include distributed processing, component/object distributed processing, and parallel processing. Alternatively, virtual computer system processing can be constructed to implement one or more of the methods or functionality as described herein.

Although the present specification describes components and functions that are implemented in particular implementations with reference to particular standards and protocols, the disclosure is not limited to such standards and protocols. For example, standards for Internet and other packet switched network transmission (e.g., TCP/IP, UDP/IP, HTML, HTTP) represent examples of the state of the art. Such standards are periodically superseded by faster or more efficient equivalents having essentially the same functions. Accordingly, replacement standards and protocols having the same or similar functions as those disclosed herein are considered equivalents thereof.

It will be understood that the steps of methods discussed are performed in one embodiment by an appropriate processor (or processors) of a processing (i.e., computer) system executing instructions (computer-readable code) stored in storage. It will also be understood that the disclosure is not limited to any particular implementation or programming technique and that the disclosure is implemented using any appropriate techniques for implementing the functionality described herein. The disclosure is not limited to any particular programming language or operating system.

It should be appreciated that in the above description of example embodiments of the present disclosure, various features are sometimes grouped together in a single embodiment, figure, or description thereof for the purpose of streamlining the disclosure and aiding in the understanding of one or more of the various inventive aspects. This method of the present disclosure, however, is not to be interpreted as reflecting an intention that the claimed embodiments require more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of the present disclosure.

Furthermore, while some embodiments described herein include some but not other features included in other embodiments, combinations of features of different embodiments are meant to be within the scope of the present disclosure, and form different embodiments, as would be understood by those skilled in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the present disclosure.

In the description provided herein, numerous specific details are set forth. However, it is understood that embodiments of the present disclosure are practiced without these specific details. In other instances, well-known methods, structures and techniques have not been shown in detail in order not to obscure an understanding of this description.

Thus, while there has been described what are believed to be the preferred embodiments of the present disclosure, those skilled in the art will recognize that other and further modifications are made thereto without departing from the spirit of the present disclosure, and it is intended to claim all such changes and modifications as falling within the scope of the present disclosure. For example, any formulas given above are merely representative of procedures that may be used. Functionality may be added or deleted from the block diagrams and operations may be interchanged among functional blocks. Steps may be added or deleted to methods described within the scope of the present disclosure.

The above disclosed subject matter is to be considered illustrative, and not restrictive, and the appended claims are intended to cover all such modifications, enhancements, and other implementations, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description. While various implementations of the disclosure have been described, it will be apparent to those of ordinary skill in the art that many more implementations and implementations are possible within the scope of the disclosure. Accordingly, the disclosure is not to be restricted except in light of the attached claims and their equivalents.

What is claimed is:

1. A computer-implemented method comprising:
receiving, by one or more processors, a request to design a formula for a product from at least one device associated with a user;
receiving, by the one or more processors, relevant data associated with the product from a plurality of data sources; and
generating, by the one or more processors, the formula for designing the product by applying one or more features of a trained machine-learning model,
wherein the trained machine-learning model has been trained by:
inputting the relevant data associated with the product into the machine-learning model;
employing a supervised learning technique to optimize the machine-learning model through iterative learning algorithms; and
evaluating performance of the machine-learning model using validation techniques; and
generating, by the one or more processors, a presentation of the formula in a user interface of the at least one device associated with the user.

2. The computer-implemented method of claim 1, wherein receiving the relevant data associated with the product comprises:
identifying, by the one or more processors, one or more properties associated with ingredients of the product, wherein the one or more properties include physical properties and chemical properties; and
extracting, by the one or more processors, the one or more properties as features for training the machine-learning model.

3. The computer-implemented method of claim 2, wherein the physical properties include one or more of texture, color, density, particle size, and viscosity of the ingredients, and wherein the chemical properties include one or more of solubility, reactivity, melting point, boiling point, toxicity, and heat capacity of the ingredients.

4. The computer-implemented method of claim 1, wherein receiving the request for the formula to design the product comprises:
generating, by the one or more processors, a presentation of at least one query in the at least one device associated with the user for additional information associated with the request;
receiving, by the one or more processors, the additional information from the at least one device associated with the user, wherein the additional information includes one or more of preference information, health-related information, or historical data; and
updating, by the one or more processors, the formula based on the additional information.

5. The computer-implemented method of claim 1, wherein generating the formula for designing the product, further comprises:
determining, by the one or more processors, ingredient interaction, ingredient specification, rheological properties, and/or adherence to regulatory standards.

6. The computer-implemented method of claim 1, wherein generating the formula for designing the product, further comprises:
analyzing, by the one or more processors, external data, proprietary data, and consumer-facing product attributes;
identifying, by the one or more processors, one or more connections between the external data, the proprietary data, and the consumer-facing product attributes to predict product outcomes; and
updating, by the one or more processors via the machine-learning model, the formula upon determining new content or updates based on the external data, the proprietary data, and the consumer-facing product attributes.

7. The computer-implemented method of claim 6, wherein the external data include one or more of molecular structure, chemical composition, and physical properties of ingredients associated with the product, wherein the proprietary data include one or more of ingredient composition and property information, processing knowledge, and quantifiable product properties, and wherein the consumer-facing product attributes include distinctive product attributes, pass/fail criteria for the formula and the product, and consumer liking correlation to revenue potential.

8. The computer-implemented method of claim 1, wherein a natural language processing (NLP) technique is utilized for analyzing textual data from the relevant data associated with the product, and wherein a network processing algorithm is utilized for modeling complex relationships within the relevant data associated with the product.

9. The computer-implemented method of claim 1, further comprising:
evaluating, by the one or more processors, a performance of the product resulting from the formula, wherein the performance of the product is based on taste, texture, appearance, and user satisfaction; and
updating, by the one or more processors, training data for training the machine-learning model based on the evaluated product performance data.

10. The computer-implemented method of claim 1, further comprising:
determining, by the one or more processors, environmental impact associated with a production process for the product based on the formula, wherein the environmental impact include one or more of carbon footprint, water usage, waste generation, and energy consumption; and
updating, by the one or more processors, training data for training the machine-learning model for prioritizing ingredient and production methods that minimize the environmental impact.

11. A system comprising:
one or more processors of a computing system; and
at least one non-transitory computer readable medium storing instructions which, when executed by the one or more processors, cause the one or more processors to perform operations comprising:
receiving a request for a formula to design a product from at least one device associated with a user;
receiving relevant data associated with the product from a plurality of data sources; and
generating the formula for designing the product by applying one or more features of a trained machine-learning model,
wherein the trained machine-learning model has been trained by:
inputting the relevant data associated with the product into the machine-learning model;
employing a supervised learning technique to optimize the machine-learning model through iterative learning algorithms; and
evaluating performance of the machine-learning model using validation techniques; and
generating a presentation of the formula in a user interface of the at least one device associated with the user.

12. The system of claim 11, wherein receiving the relevant data associated with the product comprises:
identifying one or more properties associated with ingredients of the product, wherein the one or more properties include physical properties and chemical properties; and
extracting the one or more properties as features for training the machine-learning model.

13. The system of claim 12, wherein the physical properties include one or more of texture, color, density, particle size, and viscosity of the ingredients, and wherein the chemical properties include one or more of solubility, reactivity, melting point, boiling point, toxicity, and heat capacity of the ingredients.

14. The system of claim 11, wherein receiving the request for the formula to design the product comprises:
generating a presentation of at least one query in the at least one device associated with the user for additional information associated with the request;
receiving the additional information from the at least one device associated with the user, wherein the additional information includes one or more of preference information, health-related information, or historical data; and
updating the formula based on the additional information.

15. The system of claim 11, wherein generating the formula for designing the product, further comprises:
determining ingredient interaction, ingredient specification, rheological properties, and/or adherence to regulatory standards.

16. The system of claim 11, wherein generating the formula for designing the product, further comprises:
analyzing external data, proprietary data, and consumer-facing product attributes;
identifying one or more connections between the external data, the proprietary data, and the consumer-facing product attributes to predict product outcomes; and
updating, via the machine-learning model, the formula upon determining new content or updates based on the external data, the proprietary data, and the consumer-facing product attributes.

17. The system of claim 16, wherein the external data include one or more of molecular structure, chemical composition, and physical properties of ingredients associated with the product, wherein the proprietary data include one or more of ingredient composition and property information, processing knowledge, and quantifiable product properties, and wherein the consumer-facing product attributes include distinctive product attributes, pass/fail criteria for the formula and the product, and consumer liking correlation to revenue potential.

18. A non-transitory computer readable medium, the non-transitory computer readable medium storing instructions which, when executed by one or more processors of a computing system, cause the one or more processors to perform operations comprising:
receiving a request for a formula to design a product from at least one device associated with a user;
receiving relevant data associated with the product from a plurality of data sources; and
generating the formula for designing the product by applying one or more features of a trained machine-learning model,
wherein the trained machine-learning model has been trained by:
inputting the relevant data associated with the product into the machine-learning model;
employing a supervised learning technique to optimize the machine-learning model through iterative learning algorithms; and
evaluating performance of the machine-learning model using validation techniques
generating a presentation of the formula in a user interface of the at least one device associated with the user.

19. The non-transitory computer readable medium of claim 18, wherein receiving the relevant data associated with the product comprises:
identifying one or more properties associated with ingredients of the product, wherein the one or more properties include physical properties and chemical properties,
wherein the physical properties include one or more of texture, color, density, particle size, and viscosity of the ingredients, and wherein the chemical properties include one or more of solubility, reactivity, melting point, boiling point, toxicity, and heat capacity of the ingredients; and
extracting the one or more properties as features for training the machine-learning model.

20. The non-transitory computer readable medium of claim 18, wherein receiving the request for the formula to design the product comprises:
generating a presentation of at least one query in the at least one device associated with the user for additional information associated with the request;
receiving the additional information from the at least one device associated with the user, wherein the additional information includes one or more of preference information, health-related information, or historical data; and
updating the formula based on the additional information.
